(19) United States
(12) Patent Application Publication
(10) Pub. No.: US 2025/0077744 A1
(43) Pub. Date: Mar. 6, 2025

(54) BEHAVIOR OF AN AUTONOMOUS PERCEPTION-BASED SYSTEM

(71) Applicant: Robert Bosch GmbH, Stuttgart (DE)

(72) Inventors: Jan Stellet, Stuttgart (DE); Matthias Woehrle, Bietigheim-Bissingen (DE)

(21) Appl. No.: 18/809,505

(22) Filed: Aug. 20, 2024

(30) Foreign Application Priority Data
Aug. 31, 2023 (EP) 23 19 4565.0

(51) Int. Cl. G06F 30/27; G06F 30/15; G06N 20/00

(52) U.S. Cl. CPC G06F 30/27; G06F 30/15; G06N 20/00

(57) ABSTRACT

A computer-implemented method for training a machine learning model for evaluating a behavior of an autonomous system that is configured to solve a perception task. The method includes: receiving sensor data by a perception system of the autonomous system; receiving metadata, wherein the metadata encodes an influence on a solvability of the perception task; ascertaining an error probability based on the received sensor data; providing the machine learning model, which is designed to map sensor data and metadata to an error probability for solving the perception task; and training the machine learning model based on a training data set element comprising the received sensor data, the received metadata and the ascertained error probability. A computer-implemented method for evaluating a behavior of an autonomous system that is configured to solve a perception task, is also described.

### CROSS REFERENCE

The present application claims the benefit under 35 U.S.C. § 119 of European Patent Application No. EP 23 19 4565.0 filed on Aug. 31, 2023, which is expressly incorporated herein by reference in its entirety.

### BACKGROUND INFORMATION

Autonomous systems based on at least one perception task can, for example, be fully or partially self-driving vehicles and/or robots. The at least one perception task to be solved can, for example, comprise object recognition. Alternatively or additionally, the at least one perception task to be solved can comprise, for example, semantic segmentation and/or free space recognition. The sensor data received by the perception system of the autonomous system can comprise, for example, image data (video). Alternatively or additionally, the sensor data received by the perception system of the autonomous system can comprise radar, LiDAR, ultrasonic, motion, acoustic and/or thermal data.

With regard to the goal of providing reliable and safe autonomous systems, it is desirable to be able to evaluate the behavior of the autonomous systems as best as possible already at the development stage. However, since autonomous systems are intended to be used in open contexts, such evaluations continue to pose a major challenge. In addition to test runs (of prototypes or from previous development projects), simulations are increasingly being used to solve this problem.

### SUMMARY

A first general aspect of the present invention relates to a computer-implemented method for training a machine learning model for evaluating a behavior of an autonomous system, which is configured to solve a perception task, e.g., comprising object recognition—in particular for ascertaining (upstream of the evaluation of the behavior of the autonomous system) an error probability for solving the perception task, e.g., for object recognition.

According to an example embodiment of the present invention, the method comprises receiving sensor data by a (e.g., simulated or real) perception system of the autonomous system.

The method further comprises receiving metadata, wherein the metadata encodes an influence on a solvability of the perception task, e.g., on a recognizability of the object.

The method further comprises ascertaining an error probability for solving the perception task, e.g., for object recognition, based on the received sensor data.

The method further comprises providing the machine learning model, which is designed to map (at least) sensor data and metadata to (at least) an error probability for solving the perception task, e.g., for object recognition.

The method further comprises training the machine learning model based on a training data set element comprising the received sensor data, the received metadata and the ascertained error probability.

A second general aspect of the present invention relates to a computer-implemented method for evaluating a behavior of an autonomous system that is configured to solve a perception task, e.g., comprising object recognition.

According to an example embodiment of the present invention, the method comprises simulating a perception system of the autonomous system.

The method comprises simulating a surrounding area of the perceptual system.

The method comprises providing a machine learning model that is designed and trained to map (at least) sensor data and metadata (at least) to an error probability for solving the perception task, e.g. for object recognition, wherein the metadata encodes an influence on a solvability of the perception task, e.g. on a recognizability of the object.

The method further comprises receiving sensor data and metadata.

The method further comprises applying the machine learning model to the received sensor data and metadata, wherein an error probability is ascertained.

The method further comprises evaluating the behavior of the autonomous system based on the error probability, wherein an evaluation results.

A third general aspect of the present invention relates to a computer system that is designed to execute the computer-implemented method—according to the first general aspect (or an embodiment) thereof—for training a machine learning model for evaluating a behavior of an autonomous system that is configured to solve a perception task, e.g., comprising object recognition, and/or the computer-implemented method-according to the second general aspect (or an embodiment) thereof—for evaluating a behavior of an autonomous system that is configured to solve a perception task, e.g., comprising object recognition.

A fourth general aspect of the present invention relates to a computer program that is designed to execute the computer-implemented method—according to the first general aspect (or an embodiment) thereof—for training a machine learning model for evaluating a behavior of an autonomous system that is configured to solve a perception task, e.g., comprising object recognition, and/or the computer-implemented method—according to the second general aspect (or an embodiment) thereof—for evaluating a behavior of an autonomous system that is configured to solve a perception task, e.g., comprising object recognition.

A fifth general aspect of the present invention relates to a computer-readable medium or signal that stores and/or contains the computer program according to the fourth general aspect.

The methods according to the present invention disclosed herein according to the first or second general aspect (or an embodiment thereof) are aimed at being able to better evaluate the behavior of the autonomous system, in particular already at the development stage. In particular, they are used to evaluate the impact of errors in perception on an autonomous (driving) function. If necessary and as a function of this, the autonomous system can be improved, in particular already at the development stage.

In particular, the methods according to the present invention disclosed herein aim at providing error models for a single perception system of the autonomous system. For this purpose, an error probability is calculated based on at least sensor data and metadata. The metadata comprise, e.g., a degree of occlusion of an object to be recognized, a brightness value and/or a distance value of the object to be recognized and thus encode an influence on the solvability of the perception task, e.g. on the recognizability of the object. In particular, the probability of error depends not only on the metadata, but also on the sensor data. As a result, scenarios recorded by the perception system can be better resolved and evaluated.

In the case of object recognition, for example, it may be a matter of recognizing a pedestrian. Such recognition is usually made difficult by a high degree of occlusion. Nevertheless, the pedestrian can be correctly recognized under certain circumstances if characteristic parts of the pedestrian (e.g., an arm and/or a hand) are still visible to the perception system despite the high degree of occlusion. In this case, a high probability of error does not have to be output solely due to the high degree of occlusion (as would be the case if the probability of error depended only on the metadata); rather, the probability of error can be lower thanks to the characteristic parts of the pedestrian that can still be recognized sufficiently well. Thus, the difficulty of solving the given perception task can be better quantified. As a result, high error probabilities can be output, especially when there are genuine issues with the solvability of the perception task. As a result, genuine problem cases in solving the perception task can be identified more quickly and accurately, and the autonomous system can then be specifically improved (e.g., by adding additional sensors with different viewing angles, other sensor types, adding sensor data from immediately earlier points in time, etc.). Otherwise, (unnecessary) adjustments of the autonomous system caused by spurious problems in which the perception task could still be solved satisfactorily can be avoided.

The method according to the present invention disclosed herein according to the second general aspect (or an embodiment thereof) enables a closed-loop simulation comprising a simulation of the autonomous system including its perception system and a simulation of the surrounding area of the perception system, e.g. comprising the object to be recognized. For example, such a closed-loop simulation can show which as-yet-unlabeled scenarios (also: sequences) have major impacts on the overall system. Thus, the relevant sensor data for the system behavior can be selected and, e.g., labeled from a large amount of sensor data. In addition, as described above, the autonomous system can be improved.

One goal of closed-loop simulation can be seen as ascertaining the effect of errors in the perception system on the overall system behavior. However, the perception system should not focus on errors in a specific implementation of an algorithm for solving the perception task, but rather on errors that arise due to the specific task and the surrounding area to be perceived and the associated sensor data. In one embodiment of the method according to the second aspect, this can be achieved, for example, in particular by using a plurality of further machine learning models, each designed and trained to map sensor data to solutions of the perception task, in particular to object detections.

In closed-loop simulation, time-coupled errors are of particular interest. In the methods proposed in this disclosure, the temporal coupling via the sensor data is taken into account. Thanks to the error models that specifically consider the sensor content, the temporal coupling of sensor data can also accurately represent the coupling of errors in the perception model.

### BRIEF DESCRIPTION OF THE DRAWINGS

FIGS. 1A-1D schematically illustrate a computer-implemented method for training a machine learning model for evaluating a behavior of an autonomous system that is configured to solve a perception task, in particular comprising object recognition, according to an example embodiment of the present invention.

FIG. 2 schematically illustrates a computer-implemented method for evaluating a behavior of an autonomous system that is configured to solve a perception task, in particular comprising object recognition.

### DETAILED DESCRIPTION OF EXAMPLE EMBODIMENTS

The methods according to the present invention disclosed herein are aimed at better evaluating the behavior of the autonomous system, in particular already at the development stage. Initially, a training method of a machine learning model is disclosed, followed by an application method of the machine learning model.

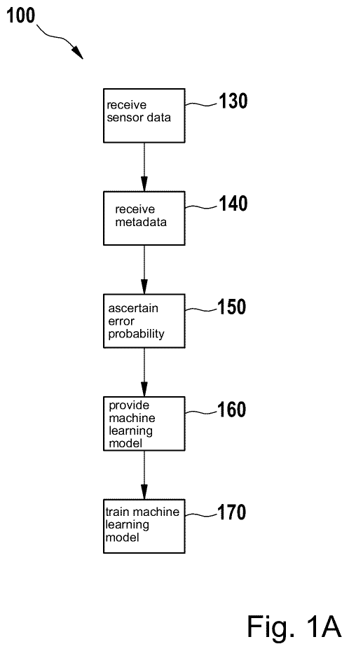

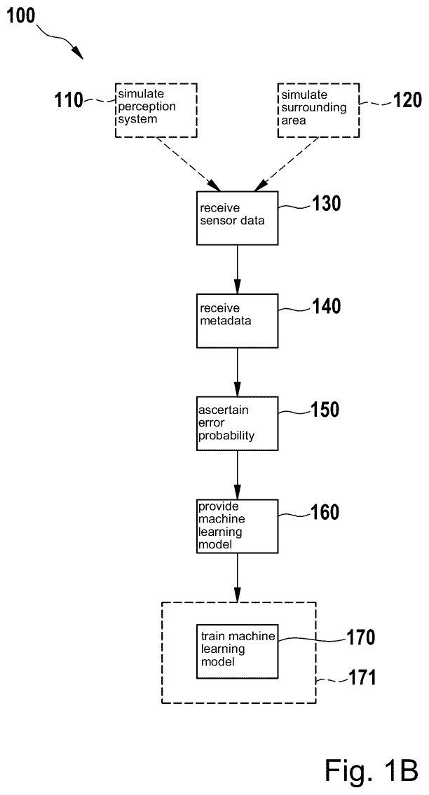

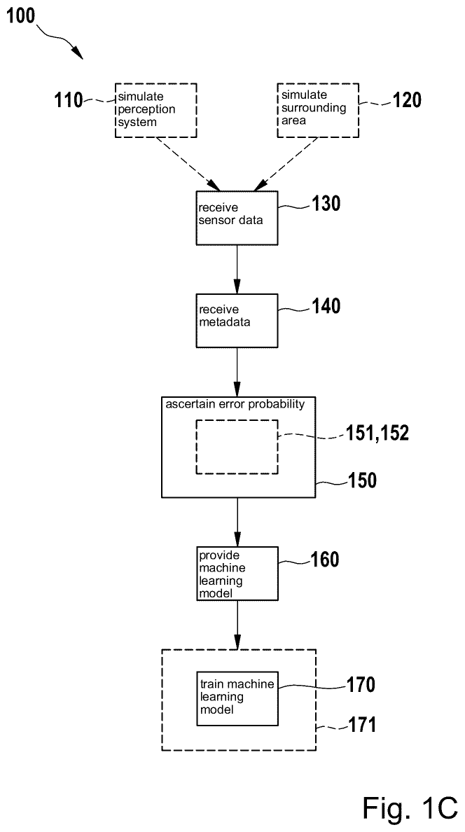

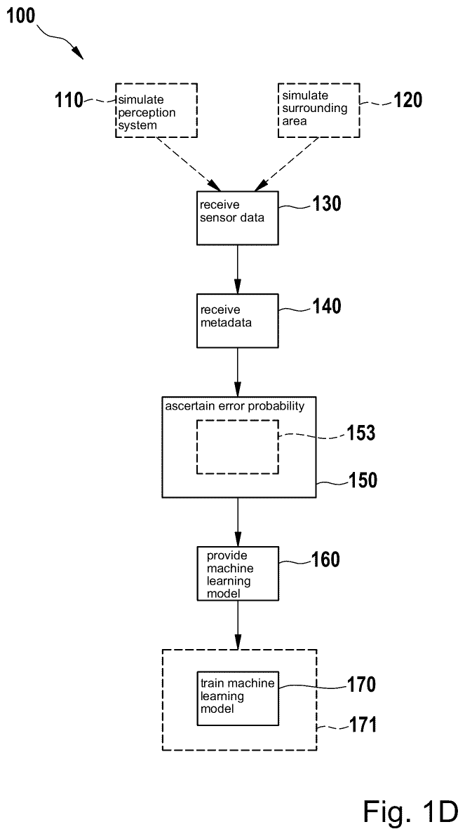

Initially, a computer-implemented method 100, schematically illustrated in FIG. 1A, is disclosed for training a machine learning model for evaluating a behavior of an autonomous system that is configured to solve a perception task. The perception task can in particular comprise the task of object recognition, i.e. the perception task or a part thereof can be solved, for example, by recognizing an object such as a pedestrian. Alternatively, the method 100 can be directed to ascertaining an error probability for solving the perception task (in particular for object recognition), the ascertaining preceding the evaluation of the behavior of the autonomous system.

The method 100 comprises receiving 130 sensor data by a perception system of the autonomous system. The autonomous system can, for example, be a fully or partially autonomous vehicle. Alternatively or additionally, the autonomous system can be a robot. The perception system can be simulative or real. In a real perception system, receiving 130 the sensor data can comprise measuring the sensor data. The perception system can comprise one or more sensor systems, each comprising one or more sensors (e.g., LIDAR, RADAR, camera, sound, ultrasound, etc.).

The method 100 further comprises receiving 140 metadata, wherein the metadata encodes an influence on a solvability of the perception task. For example, in the case of object recognition, the metadata can encode a recognizability of the object to be recognized. The metadata can, for example, be based on super-knowledge, in particular on the simulation parts 110 and 120 (see below), i.e. on simulator knowledge. Alternatively or additionally, the metadata can be ascertained, for example, from an upstream procedure based on sensor data. The metadata does not necessarily comprise information about the solvability of the perception task to be solved. Rather, the metadata comprise factors that influence the solvability of the perception task. Only in the method 200 is the solvability quantified in the form of an error probability output by the machine learning model.

The metadata can, for example, comprise the degree of occlusion of an object to be recognized. Alternatively or additionally, the metadata can comprise, for example, a brightness value. Alternatively or additionally, the metadata can comprise, for example, a distance value of the object to be recognized. Depending on the perception system and the perception task to be solved, other parameters can also be considered as metadata.

The method 100 further comprises ascertaining 150 an error probability for solving the perception task, e.g. for object recognition, based on the received 130 sensor data. The error probability can be seen as a measure of the difficulty (solvability) of the perception task to be solved.

The method 100 further comprises providing 160 (or receiving) the machine learning model, which is designed to map at least sensor data and metadata to at least one error probability for solving the perception task, in particular for object recognition. The machine learning model can, but does not have to, be trained in advance. The machine learning model can, for example, comprise or be an artificial neural network, in particular a deep artificial neural network.

The method 100 further comprises training 170 the machine learning model based on a training data set element comprising the received 130 sensor data, the received 140 metadata and the ascertained 150 error probability.

Unlike what is schematically shown in FIG. 1A, steps 130, 140 and 150 can be executed in any order.

The method 100 can comprise simulating 110 the perception system of the autonomous system, as schematically shown in FIG. 1B-1D.

Alternatively or additionally, the method 100, as also shown schematically in FIGS. 1B-1D, can comprise simulating 120 a surrounding area of the perception system, in particular an object to be recognized in the surrounding area.

The steps 110 and/or 120 are dispensable in the method 100, for example, insofar as real, i.e. measured sensor data, e.g. from test drives, is already available. Such measured sensor data can be provided with metadata, for example, through (automatic) labeling.

In the method 100, sensor data that has been measured in whole or in part by the perception system can be received 130. The associated metadata may have been generated by machine on the basis of the sensor data (e.g. via a fourth trained machine learning model) and/or manually.

Ascertaining 150 the error probability based on the received 130 sensor data can, as schematically illustrated in FIG. 1C, comprise applying 151 a plurality of further machine learning models, each designed and trained to map sensor data to solutions of the perception task, in particular to object detections, wherein each application 151 results in a perception result, in particular an object detection result, in particular a perception success or a perception failure. The plurality of other machine learning models can be replaced here by a further machine learning model. Alternatively, the plurality of additional machine learning models proves to be advantageous in that the influence of individual additional machine learning models on the error probability is averaged out. For this purpose, the further machine learning models can be different. In particular, they can be different in such a way that no two of the other machine learning models are identical.

Ascertaining 150 the error probability based on the received 130 sensor data can then, as also schematically illustrated in FIG. 1C, comprise ascertaining 152 the error probability on the basis of the perception results, in particular the object detection results, in particular on the basis of the perception successes and the perception failures. For example, the error probability can be ascertained from the ratio of the number of perception successes to the total number of perception successes and perception failures.

In another embodiment, schematically shown in FIG. 1D, ascertaining 150 the error probability based on the received 130 sensor data can comprise applying 153 a third machine learning model that is designed and trained to map sensor data and, optionally, metadata to an error probability for solving the perception task, wherein the error probability is ascertained 150.

The method 100 can, as schematically shown in FIGS. 1B-1D, comprise the training 171 of the machine learning model based on a training data set, which comprises a plurality of training data set elements. Each training dataset element may have been created following steps of the method 100. The plurality of training dataset elements should be as large as possible in order to obtain a meaningful trained machine learning model.

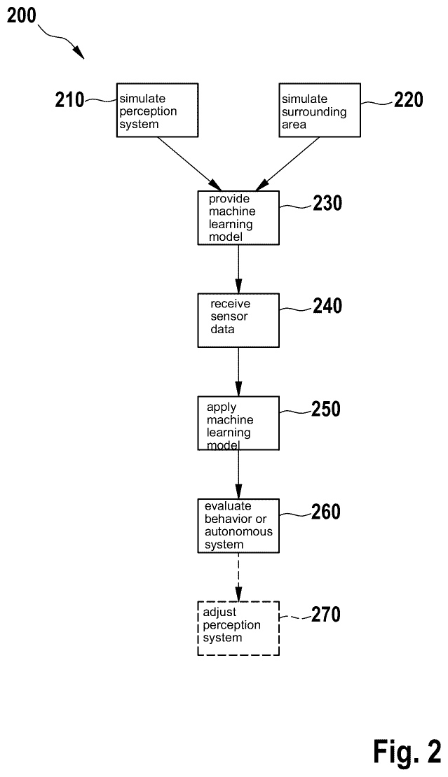

Also disclosed is a computer-implemented method 200, schematically shown in FIG. 2, for evaluating a behavior of an autonomous system that is configured to solve a perception task. The perception task can in particular comprise the task of object recognition, i.e. the perception task or a part thereof can be solved, for example, by recognizing an object such as a pedestrian.

The method 200 comprises the simulation 210 of a perception system of the autonomous system.

The method 200 further comprises the simulation 220 of a surrounding area of the perception system.

Thanks to the simulation steps 210 and 220, the method can be executed very often and is in particular suitable for Monte Carlo analyses.

The method 200 further comprises providing 230 (or receiving) a machine learning model that is designed and trained to map at least sensor data and metadata at least to an error probability for solving the perception task, in particular for object recognition. As already described in connection with the method 100, the metadata also encode an influence on the solvability of the perception task, in particular on the recognizability of the object. The machine learning model may have been trained using the method 100 170, 171.

The method 200 further comprises receiving 240 sensor data and metadata. The metadata can, for example, be based on super knowledge, in particular on the simulation parts 210 and 220, i.e. on simulator knowledge. Alternatively or additionally, the metadata can be ascertained, for example, from an upstream procedure based on sensor data. The metadata does not necessarily comprise information about the solvability of the perception task to be solved. Rather, the metadata comprise factors that influence the solvability of the perception task. Only in method 200 is the solvability quantified in the form of an error probability output by the machine learning model in step 240.

As already described, the metadata can, for example, comprise a degree of occlusion of an object to be recognized. Alternatively or additionally, the metadata can comprise, for example, a brightness value. Alternatively or additionally, the metadata can comprise, for example, a distance value of the object to be recognized. Depending on the perception system and the perception task to be solved, other parameters can also be considered as metadata.

The method 200 further comprises applying 250 the machine learning model to at least the received 240 sensor data and metadata, wherein at least one error probability is ascertained.

The method 200 further comprises evaluating 260 the behavior of the autonomous system based on the error probability, wherein an evaluation results. The evaluation 260 can take place over a period of time.

Unlike the schematic representation shown in FIG. 2, steps 230 and 240 can take place in any order or simultaneously. Steps 210 and 220 can, but do not have to, take place simultaneously.

Evaluating 260 the behavior of the autonomous system can comprise rolling a die for at least one event based on the error probability, wherein the at least one event is identified as an error event or a non-error event. For example, rolling a die can be realized by forming an empirical distribution function based on the error probability and evaluating its inverse on a (pseudo-) random number on the real interval [0, 1].

In particular, evaluating 260 the behavior of the autonomous system can comprise (e.g. as in Monte Carlo simulations) rolling a die for a plurality of events based on the error probability.

Evaluating 260 the behavior of the autonomous system can be based on at least two events at different points in time. Evaluating 260 the behavior of the autonomous system can be based on a plurality of events.

The method 200 can comprise the adjustment 270 of the perception system of the autonomous system based on the evaluation. This can improve the perception system and/or the autonomous system; in particular, the reliability and safety of the autonomous system can be increased.

The (more precisely: solving of the) perception task in both methods 100, 200 can comprise, for example, object recognition. Alternatively or additionally, the (more precisely: solving of the) perception task can comprise semantic segmentation. Alternatively or additionally, the (more precisely: solving of the) perception task can comprise free space recognition. Further perception tasks or their combinations are possible.

In both methods 100, 200, the machine learning model can be composed of one or more submodels. For example, the machine learning model can comprise a submodel for near objects and a submodel for far objects. In this case, for example, based on the metadata and/or based on other input variables, the submodel that is to be trained 170, 171 or applied in order to calculate the error probability 250 can initially be selected.

Furthermore, a computer system is disclosed which is designed to carry out the computer-implemented method 100 for training a machine learning model for evaluating a behavior of an autonomous system that is configured to solve a perception task, in particular comprising object recognition. Alternatively or additionally, the computer system can be designed to execute the computer-implemented method 200 for evaluating a behavior of an autonomous system that is configured to solve a perception task, in particular comprising object recognition. The computer system can comprise a processor and/or a working memory.

Furthermore, a computer program is disclosed which is designed to carry out the computer-implemented method 100 for training a machine learning model for evaluating a behavior of an autonomous system that is configured to solve a perception task, in particular comprising object recognition. Alternatively or additionally, the computer program can be designed to execute the computer-implemented method 200 for evaluating a behavior of an autonomous system that is configured to solve a perception task, in particular comprising object recognition. The computer program can be present, for example, in interpretable or in compiled form. For execution, it can (even in parts) be loaded into the RAM of a computer, for example as a bit or byte sequence.

Also disclosed according to the present invention is a computer-readable medium or signal that stores and/or contains the computer program. The medium can comprise, for example, any one of RAM, ROM, EPROM, HDD, SDD, . . . , on/in which the signal is stored.

What is claimed is:

1. A computer-implemented method for training a machine learning model for evaluating a behavior of an autonomous system that is configured to solve a perception task including object recognition, the method comprising:
receiving sensor data by a perception system of the autonomous system;
receiving metadata, wherein the metadata encodes an influence on a solvability of the perception task including a recognizability of the object;
ascertaining an error probability for solving the perception task based on the received sensor data;
providing the machine learning model, which is configured to map sensor data and metadata to an error probability for solving the perception task; and
training the machine learning model based on a training data set element including the received sensor data, the received metadata, and the ascertained error probability.

2. The method according to claim 1, further comprising:
simulating the perception system of the autonomous system;
simulating a surrounding area of the perception system including an object to be recognized in the surrounding area.

3. The method according to claim 1, wherein the sensor data are measured by the perception system; and wherein the metadata were generated: (i) by machine based on the sensor data and/or (ii) manually.

4. The method according to claim 1, wherein the ascertaining of the error probability based on the received sensor data includes:
applying a plurality of further machine learning models, each designed and trained to map sensor data to solutions of the perception task including to object detections, wherein each application results in a perception result including a perception success or a perception failure;
ascertaining the error probability based on the perception results including the object detection results including based on the perception successes and the perception failures.

5. The method according to claim 4, wherein the further machine learning models are different from one another.

6. The method according to claim 1, wherein the ascertaining of the error probability based on the received sensor data includes:
applying a third machine learning model that is designed and trained to map sensor data to an error probability for solving the perception task, wherein the error probability is ascertained.

7. The method according to claim 1, further comprising:
training the machine learning model based on a training data set including a plurality of training data set elements.

8. A computer-implemented method for evaluating a behavior of an autonomous system that is configured to solve a perception task including object recognition, the method comprising:
simulating a perception system of the autonomous system;
simulating a surrounding area of the perception system;
providing a machine learning model that is configured and trained to map sensor data and metadata to an error probability for solving the perception task including for object recognition, wherein the metadata encodes an influence on a solvability of the perception task including recognizability of the object;
receiving sensor data and metadata;
applying the machine learning model to the received sensor data and metadata, wherein an error probability is ascertained;
evaluating a behavior of the autonomous system based on the error probability, wherein an evaluation results.

9. The method according to claim 8, wherein the evaluating of the behavior of the autonomous system comprises rolling a die for at least one event based on the error probability, wherein the at least one event is identified as an error event or a non-error event.

10. The method according to claim 9, wherein the evaluating of the behavior of the autonomous system is based on at least two events at different points in time.

11. The method according to claim 10, wherein the evaluating of the behavior of the autonomous system is based on a plurality of events.

12. The method according to claim 8, further comprising:
adjusting the perception system of the autonomous system based on the evaluation.

13. The method according to claim 8, wherein the machine learning model has been trained by:
receiving sensor data by a perception system of the autonomous system;
receiving metadata, wherein the metadata encodes an influence on a solvability of the perception task including a recognizability of the object;
ascertaining an error probability for solving the perception task based on the received sensor data;
providing the machine learning mode; and
training the machine learning model based on a training data set element including the received sensor data, the received metadata, and the ascertained error probability.

14. The method according to claim 8, wherein the metadata comprise a degree of occlusion of an object to be recognized, and/or a brightness value and/or a distance value of the object to be recognized.

15. The method according to claim 8, wherein the perception task includes object recognition and/or semantic segmentation and/or free space recognition.

16. A computer system configured to:
(i) train a machine learning model for evaluating a behavior of an autonomous system that is configured to solve a perception task including object recognition by:
receiving sensor data by a perception system of the autonomous system,
receiving metadata, wherein the metadata encodes an influence on a solvability of the perception task including a recognizability of the object,
ascertaining an error probability for solving the perception task based on the received sensor data,
providing the machine learning model, which is configured to map sensor data and metadata to an error probability for solving the perception task, and
training the machine learning model based on a training data set element including the received sensor data, the received metadata, and the ascertained error probability; and/or
(ii) evaluate a behavior of an autonomous system that is configured to solve a perception task including object recognition by:
simulating a perception system of the autonomous system,
simulating a surrounding area of the perception system,
providing a machine learning model that is configured and trained to map sensor data and metadata to an error probability for solving the perception task including for object recognition, wherein the metadata encodes an influence on a solvability of the perception task including recognizability of the object,
receiving sensor data and metadata,
applying the machine learning model to the received sensor data and metadata, wherein an error probability is ascertained,
evaluating a behavior of the autonomous system based on the error probability, wherein an evaluation results.

17. A non-transitory computer readable medium on which is stored a computer program, the computer program, when executed by a computer, causing the computer to perform the following:
(i) training a machine learning model for evaluating a behavior of an autonomous system that is configured to solve a perception task including object recognition, including:
receiving sensor data by a perception system of the autonomous system,
receiving metadata, wherein the metadata encodes an influence on a solvability of the perception task including a recognizability of the object,
ascertaining an error probability for solving the perception task based on the received sensor data,
providing the machine learning model, which is configured to map sensor data and metadata to an error probability for solving the perception task, and
training the machine learning model based on a training data set element including the received sensor data, the received metadata, and the ascertained error probability; and/or
(ii) evaluating a behavior of an autonomous system that is configured to solve a perception task including object recognition, including:
simulating a perception system of the autonomous system,
simulating a surrounding area of the perception system,
providing a machine learning model that is configured and trained to map sensor data and metadata to an error probability for solving the perception task including for object recognition, wherein the metadata encodes an influence on a solvability of the perception task including recognizability of the object,
receiving sensor data and metadata,
applying the machine learning model to the received sensor data and metadata, wherein an error probability is ascertained,
evaluating a behavior of the autonomous system based on the error probability, wherein an evaluation results.
